(19) United States
(12) Patent Application Publication
(10) Pub. No.: US 2026/0096211 A1
(43) Pub. Date: Apr. 2, 2026

(54) LATERAL HIGH VOLTAGE SEMICONDUCTOR DEVICE AND METHOD FOR MANUFACTURING

(71) Applicant: Infineon Technologies Austria AG, Villach (AT)

(72) Inventors: Franz Hirler, Isen (DE); Lars Müller-Meskamp, Dresden (DE); Tom Peterhänsel, Dresden (DE); Fabian Geisenhof, München (DE); Annett Winzer, Dresden (DE)

(21) Appl. No.: 19/328,744

(22) Filed: Sep. 15, 2025

(30) Foreign Application Priority Data
Sep. 30, 2024 (DE) 102024209536.2
Aug. 12, 2025 (DE) 102025132026.8

(51) Int. Cl. H10D 86/00; H10D 86/01

(52) U.S. Cl. CPC H10D 86/201; H10D 86/01

(57) ABSTRACT

A semiconductor device includes a semiconductor body having front and back sides, with a device region within the semiconductor body at the front side and including at least one lateral semiconductor element, and a first doped region of a second conductivity type between the device region and the back side. The first doped region overlaps first portions of the back side. At least one second doped region within the semiconductor body overlaps second portions of the back side. The first doped region is arranged between the device region and the second doped region. An insulating layer at least partly covers the back side of the semiconductor body. The second doped region differs from the first doped region in at least one of a doping concentration by at least 20% and/or a conductivity type of the doping. Both the first portions and the second portions laterally overlap with the insulating layer.

### TECHNICAL FIELD

The present disclosure relates to a semiconductor device and a method for manufacturing the same. Specifically, the present disclosure pertains to semiconductor devices with improved doping configurations and insulating structures on the back side, enabling enhanced electrical performance and reliability, as well as methods for fabricating such devices with precise control over doping profiles and insulating layer placement.

### BACKGROUND

High voltage semiconductor devices in CMOS technology (complementary metal oxide semiconductors) form an interface between standard CMOS devices with input voltages up to 5V on the one hand and industrial or consumer circuits operating with signal voltage levels above 30V on the other. Applications for such semiconductor devices exist in all kinds of power conversion and electrical drives up to the kV range, e.g., in power converters, robotics and the automotive industry. High voltage semiconductor devices typically include a low voltage part operating in a low voltage domain and a high voltage part operating in a high voltage domain. In the low voltage part, most of the signal processing is done at low operating voltage. The high voltage part operates at higher voltage level. The low voltage part and the high voltage part provide signal interfaces for power semiconductors using higher voltage levels and/or having higher current driving and sinking capability. The electric potentials of the different voltage domains can differ by several 100V up to some 1000V. An example of such a high voltage semiconductor device is a gate driver circuit. Gate driver circuits allow a microcontroller or DSP (digital signal processor) to efficiently turn on and off power semiconductor switches. Such semiconductor devices include high voltage semiconductor elements for exchanging electric power and/or electric signals between the CMOS circuits in the different voltage domains.

There is a constant need to improve signal transmission in semiconductor devices with HV semiconductor elements with little additional effort.

### SUMMARY

High voltage semiconductor devices typically include a high voltage device with a large potential transition region formed between first doping regions associated with the low voltage part and second doping regions associated with the high voltage part. LDMOS (laterally diffused metal oxide semiconductor field effect transistors) include drain extension regions extending into the potential transition region, wherein the drain extensions are not necessarily laterally diffused but may also be formed by shallow ion implantation. HV diodes include anode extension regions extending into the potential transition region. The extension regions may increase the parasitic capacitances of the HV semiconductor element and the semiconductor volume from which leakage current can be collected.

The present disclosure is related to a semiconductor device that comprises a semiconductor body having a front side and a back side opposite to the front side, a device region within the semiconductor body at the front side, wherein the device region comprises at least one lateral semiconductor element, and a first doped region of a second conductivity type between the device region and the back side, wherein the first doped region overlaps first portions of the back side. The semiconductor device further comprises at least one second doped region within the semiconductor body, wherein the at least one second doped region overlaps second portions of the back side, wherein the first doped region is arranged between the device region and the at least one second doped region and an insulating layer at least partly covering the back side of the semiconductor body. The at least one second doped region differs from the first doped region in at least one of the doping concentration by at least 20% and/or the conductivity type of the doping. In other words, the at least one second doped regions differ in their doping concentration by at least 20% from the doping concentration of the first doped region and/or the conductivity type of the doping of the second regions is opposite to the conductivity type of the first doped region. Both the first portions of the back side and the second portions of the back side laterally overlap with the insulating layer.

The present disclosure is related to a method for manufacturing a semiconductor device comprising the following steps: providing a semiconductor body having a front side and a back side opposite to the front side, a device region within the semiconductor body at the front side, wherein the device region comprises at least one lateral semiconductor element; and a first doped region of a second conductivity type between the device region and the back side, wherein the first doped region overlaps first portions of the back side; Forming at least one second doped region within the semiconductor body, wherein the at least one second doped region overlaps second portions of the back side, wherein the first doped region is arranged between the device region and the at least one second doped region; and Forming an insulating layer at least partly covering the back side of the semiconductor body. The at least one second doped region differs from the first doped region in at least one of the doping concentration by at least 20%, and/or the conductivity type of the doping. Both the first portions of the back side and the second portions of the back side laterally overlap with the insulating layer.

Those skilled in the art will recognize additional features and advantages upon reading the following detailed description, and upon viewing the accompanying drawings.

A first aspect of the invention provides a semiconductor device, comprising a semiconductor body having a front side and a back side opposite to the front side; a device region within the semiconductor body at the front side, wherein the device region comprises at least one lateral semiconductor element; a first doped region of a second conductivity type between the device region and the back side, wherein the first doped region overlaps first portions of the back side; at least one second doped region within the semiconductor body, wherein the at least one second doped region overlaps second portions of the back side, wherein the first doped region is arranged between the device region and the at least one second doped region; and an insulating layer at least partly covering the back side of the semiconductor body; wherein the at least one second doped region differs from the first doped region in at least one of the doping concentration by at least 20%, and/or the conductivity type of the doping; wherein both the first portions of the back side and the second portions of the back side laterally overlap with the insulating layer.

The subject matter describes a semiconductor device with specific structural and material characteristics. A “semiconductor device” refers to an electronic component that exploits the electronic properties of semiconductor materials, such as silicon, to perform its function. The “semiconductor body” is the physical structure of the device, typically made of a semiconductor material, and it has a “front side” and a “back side,” which are opposite surfaces of the body. The “device region” is a specific area within the semiconductor body located at the front side, where at least one “lateral semiconductor element” is formed. A lateral semiconductor element may refer to a component, such as a transistor (e.g. MOSFET of junction transistor) or diode, that operates with current flow parallel to the surface of the semiconductor body.

The “first doped region” is a part of the semiconductor body that has been intentionally infused with impurities to create a “second conductivity type”. The doping of the first doped region may be a background doping of the semiconductor body. The first doped region is positioned between the device region and the back side and overlaps specific areas, referred to as “first portions,” of the back side. The “second doped region” is another doped area within the semiconductor body, overlapping different areas, referred to as “second portions,” of the back side. The first doped region is partly situated between the device region and the second doped region. The term “doping” refers to the process of adding impurities to a semiconductor to modify its electrical properties, and “doping concentration” indicates the amount of impurity added. The “conductivity type” refers to whether the doped region is n-type (negative charge carriers) or p-type (positive charge carriers).

The aspect specifies that the first and second doped regions differ in at least one characteristic: Either the doping concentration differs by at least 20% between the first and the second doped region or the conductivity type differs between the first and the second doped region. This distinction allows for tailored electrical properties in different regions of the device.

The “insulating layer” is a material layer that electrically isolates parts of the semiconductor body and at least partially covers the back side. Additionally, both the first and second portions of the back side, which correspond to the first and second doped regions, laterally overlap with the insulating layer. This arrangement ensures that the insulating layer interacts with both doped regions, fully insulating both.

The described structure offers advantages such as improved control over electrical characteristics, enhanced isolation between regions, and the ability to optimize the device for specific applications by varying doping concentrations or types. The lateral overlap of the insulating layer with both doped regions may contribute to better thermal management, reduced leakage currents, or increased durability of the device.

In a first implementation of the device according to the first aspect, the second doped region is of the second conductivity type.

The implementation introduces a specific feature where the second doped region is defined to be of the same conductivity type as the first doped region, which is the second conductivity type. This modification refines the structural and functional relationship between the first and second doped regions within the semiconductor body. By specifying that the second doped region shares the same conductivity type as the first doped region, the implementation narrows the scope of the invention to a configuration where both regions contribute to a similar type of charge carrier behavior, such as electron or hole conduction, depending on whether the second conductivity type is n-type or p-type. In this case, the doping concentration of the first and the second doped region differs by at least 20%. The insulating layer ensures electrical isolation while allowing the doped regions to interact indirectly through their influence on the electric field distribution within the semiconductor body. The new feature brought by this implementation is the homogeneity in conductivity type between the first and second doped regions, which can simplify the manufacturing process by reducing the need for additional doping steps with different materials or concentrations. Furthermore, this feature may enhance the device's performance in applications where uniformity in charge carrier type is critical, such as in power devices or high-frequency applications.

In a further implementation of the device according to the first aspect, the doping concentration of the at least one second doped region is at least one magnitude higher than the doping concentration of the first doped region. According to this implementation, both the first and the second doped region may have the same or a different conductivity type.

The implementation introduces a specific mechanism of differentiation between the first doped region and the at least one second doped region by specifying that the doping concentration of the second doped region is at least one magnitude higher than that of the first doped region. This feature enhances the functional distinction between the two regions within the semiconductor body, thereby influencing the electrical and operational characteristics of the device. The aspect already establishes the presence of a first doped region and at least one second doped region, with the latter differing from the former in either doping concentration or conductivity type. The implementation refines this distinction by quantifying the difference in doping concentration, ensuring that the second doped region exhibits a significantly higher level of doping. This substantial difference in doping concentration can lead to enhanced control over the electrical properties, such as carrier mobility, resistance, and breakdown voltage, within the semiconductor device. The communication between the components, specifically the first doped region, the second doped region, and the device region, is influenced by this doping disparity. The higher doping concentration in the second doped region can create a stronger electric field or a more pronounced potential barrier, which may be utilized to optimize the performance of the lateral semiconductor element in the device region. Additionally, the interaction between the insulating layer and the back side of the semiconductor body, which overlaps both the first and second doped regions, remains consistent with the aspect, but the new feature introduced in the implementation ensures that the second doped region's electrical behavior is distinctly different from that of the first doped region.

In a further implementation of the device according to the first aspect, the first doped region and/or the at least one second doped region adjoin the back side.

The implementation introduces a specific structural relationship between the first doped region and/or the at least one second doped region and the back side of the semiconductor body, specifying that these doped regions adjoin the back side. This feature refines the spatial configuration of the semiconductor device by ensuring direct physical contact or immediate proximity between the doped regions and the back side. The mechanism of communication between components in this context is primarily structural and electrical. By adjoining the back side, the doped regions are positioned to facilitate efficient charge carrier movement or electrical interaction between the doped regions and the back side, which may be critical for the device's performance, such as in terms of conductivity, breakdown voltage, or thermal dissipation. The new feature brought by this implementation enhances the design flexibility and functional optimization of the semiconductor device. It allows for precise engineering of the electrical and thermal properties of the device by controlling the interface between the doped regions and the back side. This could be particularly advantageous in applications where the back side serves as a contact surface, a heat sink, or a region for further processing. This feature also complements the insulating layer described in the aspect, as the direct adjacency of the doped regions to the back side could influence how the insulating layer interacts with the underlying semiconductor material, potentially affecting the device's overall insulation and reliability. By specifying that either or both of the doped regions adjoin the back side, both doped region are fully isolated against a surrounding.

In a further implementation of the device according to the first aspect, two different ones of the second portions of the back side are completely separated from each other by one or more of the first portions.

The implementation introduces a structural refinement to the semiconductor device by specifying that two distinct portions of the back side, which correspond to the second doped regions, are entirely separated from one another by one or more portions of the back side that correspond to the first doped region. This feature establishes a spatial and electrical isolation mechanism between the second doped regions, mediated by the intervening first doped region. The communication between components in this context is primarily defined by the spatial arrangement and the doping characteristics of the regions. The first doped region, being of a different conductivity type or doping concentration compared to the second doped regions, acts as a barrier or separator, ensuring that the second doped regions do not directly interact or overlap. This separation can influence the electrical behavior of the device, such as reducing parasitic interactions, minimizing leakage currents, or enhancing the control over the lateral semiconductor element's operation within the device region. The new feature brought by this implementation is the explicit requirement for complete separation of the second doped regions by the first doped region, which adds a layer of design specificity and functional differentiation to the semiconductor device. This structural arrangement can be particularly advantageous in applications where precise control over the electrical characteristics of the back side is critical, such as in power devices, high-frequency applications, or devices requiring robust isolation between different functional regions. By mandating complete separation, the implementation ensures that the second doped regions are not only distinct in their doping properties but are also physically and electrically isolated, which can contribute to improved device performance, reliability, and manufacturability. This feature also complements the insulating layer on the back side, as the insulating layer's overlap with both the first and second portions of the back side further reinforces the isolation and electrical integrity of the device. The implementation thus refines the aspect by introducing a specific spatial configuration that enhances the functional and operational characteristics of the semiconductor device.

In a further implementation of the device according to the first aspect, the first portions of the back side are completely covered by the insulating layer.

The implementation introduces a specific structural feature that enhances the insulation properties of the semiconductor device by stipulating that the first portions of the back side are entirely covered by the insulating layer. This ensures that the first doped region, which is located between the device region and the back side, is completely insulated at the back side by the insulating layer. The mechanism of communication between components in this context is primarily physical and electrical isolation, as the insulating layer acts as a barrier that prevents direct electrical interaction or leakage between the first doped region and any external environment or adjacent regions at the back side. This feature brings a significant improvement in the device's operational reliability and performance by minimizing the risk of unintended electrical conduction or interference that could arise from exposed doped regions. By fully encapsulating the first portions of the back side with the insulating layer, the implementation ensures that the first doped region is effectively shielded, which is particularly advantageous in applications requiring high voltage isolation or where the semiconductor device is exposed to harsh environmental conditions. Furthermore, the complete insulation of the first doped region at the back side may facilitate more precise control over the electrical characteristics of the device, as it eliminates potential variability introduced by partial exposure of the doped region. This feature complements the aspect's broader structure by refining the interaction between the insulating layer and the first doped region, thereby reinforcing the device's design for improved electrical isolation and stability. The implementation's focus on complete coverage underscores a deliberate design choice aimed at optimizing the semiconductor device's performance and durability in demanding applications.

In a further implementation of the device according to the first aspect, the second portions of the back side are completely covered by the insulating layer.

The implementation introduces a specific structural feature that enhances the insulation properties of the semiconductor device by stipulating that the second portions of the back side are entirely covered by the insulating layer. This ensures that each of the at least one second doped region is completely insulated at the back side by the insulating layer. By requiring complete coverage of the second portions of the back side, the implementation effectively isolates the second doped regions from external electrical or environmental influences that might otherwise interact with the back side.

In a further implementation of the device according to the first aspect, one or more of the at least one second doped region is shaped as a closed loop.

The implementation introduces a specific geometric configuration for one or more of the second doped regions, specifying that these regions are shaped as closed loops, such as circles or ovals. This feature adds a new structural characteristic to the semiconductor device, which may influence the interaction between the second doped regions and other components of the device. The closed loop ensures a full insulating of the device region In a lateral direction. For instance, the closed-loop configuration may improve the distribution of electric fields within the semiconductor body, thereby reducing localized stress or hotspots that could arise in irregularly shaped regions. The closed-loop shape may also influence the lateral overlap with the insulating layer, ensuring a more stable and controlled interface. This feature could be particularly advantageous in applications where precise control over the electrical characteristics of the back side of the semiconductor body is critical. By specifying a closed-loop shape, the implementation introduces a design element that could be tailored to optimize the device for specific operational requirements, such as enhanced breakdown voltage, reduced leakage currents, or improved thermal dissipation.

In a further implementation of the device according to the first aspect, wherein, in a top view, a plurality of the at least one second doped regions are arranged according to a dot matrix.

The implementation introduces a specific arrangement for the second doped regions within the semiconductor device, specifying that, in a top view, a plurality of these second doped regions are organized in a dot matrix pattern. This feature adds a geometric and spatial configuration to the second doped regions, which were previously defined in the aspect only in terms of their overlap with the back side, their differentiation from the first doped region in doping concentration or conductivity type, and their lateral overlap with the insulating layer. The dot matrix arrangement implies a regular, repeating pattern of the second doped regions, which could enhance the uniformity of electrical or thermal properties across the back side of the semiconductor body. This configuration may also facilitate improved control over the electrical characteristics of the device, such as breakdown voltage or current distribution, by ensuring a predictable and evenly distributed doping profile.

In a further implementation of the device according to the first aspect, wherein, in a top view, a first plurality of the at least one second doped regions are arranged according to a first dot matrix inside the closed loop; and/or a second plurality of the at least one second doped regions are arranged according to a second dot matrix outside the closed loop.

The implementation introduces a spatial arrangement of the second doped regions within the semiconductor device, specifically in relation to a closed loop structure. The implementation specifies that, for example, in a top view of the semiconductor device, a first plurality of the second doped regions is arranged in a first dot matrix pattern inside the closed loop, while a second plurality of the second doped regions is arranged in a second dot matrix pattern outside the closed loop. This arrangement provides a structured and organized distribution of the second doped regions, which may enhance the electrical performance of the device by optimizing the placement of these regions relative to the closed loop. The closed loop itself, while not explicitly detailed in this implementation, may serve as a boundary or functional feature within the semiconductor body, and the dot matrix patterns of the second doped regions inside and outside this loop suggest a deliberate design to achieve specific operational benefits.

In a further implementation of the device according to the first aspect, further comprising an insulating trench extending from the front side to the back side of the semiconductor body laterally confining the device region.

The implementation introduces an insulating trench that extends from the front side to the back side of the semiconductor body, which laterally confines the device region. This feature provides a specific mechanism of communication between the components by physically and electrically isolating the device region from other regions within the semiconductor body. For example, those other regions comprise another voltage domain, e.g. a high voltage domain or a low voltage domain of a gate driver. The insulating trench may isolate the high voltage domain or a low voltage domain of a gate driver against each other. An isolation voltage may be greater than 200V or greater than 600V or even 1200V. The insulating trench serves as a boundary that prevents lateral electrical interference or leakage between the device region and adjacent regions, such as the first doped region or the at least one second doped region. This isolation mechanism enhances the operational integrity of the lateral semiconductor element within the device region by ensuring that its performance is not adversely affected by parasitic effects or unintended interactions with other parts of the semiconductor body. The new feature brought by this implementation is the introduction of a structural and functional barrier that improves the device's reliability and efficiency. By extending from the front side to the back side, the insulating trench ensures comprehensive isolation throughout the entire thickness of the semiconductor body, which is particularly beneficial in applications requiring high precision and minimal cross-talk between different regions. This structural addition complements the insulating layer already present on the back side by providing an additional layer of isolation, but it does so in a manner that is three-dimensional, as opposed to the planar coverage of the insulating layer. Furthermore, the trench's ability to laterally confine the device region may allow for more compact designs, as it reduces the need for additional spacing between regions to prevent interference. This feature, therefore, not only enhances the electrical performance of the semiconductor device but also contributes to its overall design flexibility and scalability. By integrating this insulating trench, the semiconductor device achieves a higher level of functional isolation and structural integrity, which can be particularly advantageous in complex integrated circuits or advanced semiconductor applications.

In a further implementation of the device according to the first aspect, the insulating trench comprises a trench dielectric adjoining the insulating layer.

The implementation introduces a specific structural enhancement to the semiconductor device by detailing the interaction between the insulating trench and the insulating layer. The insulating trench, which is a structural feature within the semiconductor body, is specified to include a trench dielectric that adjoins the insulating layer. This configuration establishes a direct physical and functional relationship between the trench dielectric and the insulating layer, ensuring continuity in insulation and potentially improving the electrical isolation properties of the device. The trench dielectric serves as a medium that not only reinforces the insulating properties of the trench but also integrates seamlessly with the insulating layer covering the back side of the semiconductor body. This structural arrangement can enhance the device's ability to manage leakage currents and maintain electrical isolation between different regions of the semiconductor body. The new feature brought by this implementation is the explicit definition of the trench dielectric's role and its adjacency to the insulating layer, which may contribute to improved device reliability, reduced parasitic effects, and better thermal management.

In a further implementation of the device according to the first aspect, wherein, in a top view, the insulating trench is shaped as a closed loop, e.g. a circle or oval.

The implementation introduces a specific structural configuration for the insulating trench within the semiconductor device, specifying that, in a top view, the trench is shaped as a closed loop, such as a circle or oval. This feature builds upon the broader framework of the aspect by refining the geometric arrangement of the insulating trench, which is a critical component in the device's architecture. The closed-loop configuration of the trench provides a mechanism for enhanced electrical isolation between different regions of the semiconductor body, particularly between the first doped region and the at least one second doped region. This isolation is achieved by creating a continuous barrier that prevents lateral electrical interference or leakage currents, thereby improving the overall performance and reliability of the semiconductor device. The circular or oval shape of the trench further contributes to uniformity in the isolation effect, as these geometries lack sharp corners that could otherwise concentrate electric fields and lead to localized breakdowns or inefficiencies. The new feature also facilitates a more predictable and stable distribution of electric fields within the semiconductor body, which is particularly advantageous in high-performance or high-voltage applications. Additionally, the closed-loop design may simplify the manufacturing process by providing a consistent and repeatable pattern for trench formation, which can be advantageous in terms of scalability and production yield. This geometric refinement also aligns with the insulating layer's role in covering portions of the back side, ensuring that the insulating trench integrates seamlessly with the overall device structure.

In a further implementation of the device according to the first aspect, the at least one second doped region adjoins the whole inside of the insulating trench laterally.

The implementation introduces a specific spatial relationship between the second doped region and the insulating trench, specifying that the second doped region adjoins the entire interior surface of the insulating trench laterally. This feature establishes a direct and continuous interface between the second doped region and the insulating trench, which may enhance the electrical isolation or interaction between the second doped region and other regions of the semiconductor device. The mechanism of communication between components in this context is primarily structural and spatial, as the second doped region's lateral adjacency to the insulating trench ensures that any electrical or physical effects, such as charge distribution, field modulation, or thermal conduction, are influenced by this close proximity. This adjacency could also serve to confine or direct electrical fields within the semiconductor body, potentially improving the performance or reliability of the lateral semiconductor element in the device region. The new feature brought by this implementation is the explicit requirement for the second doped region to laterally adjoin the entire inside of the insulating trench, which may provide enhanced control over the electrical characteristics of the device, such as leakage currents, breakdown voltage, or parasitic capacitance. This structural arrangement could also facilitate more precise engineering of the semiconductor device's behavior by ensuring that the insulating trench and the second doped region interact in a predictable and uniform manner across their entire interface. Overall, the implementation refines the structural and functional aspects of the semiconductor device by emphasizing the comprehensive lateral adjacency of the second doped region to the insulating trench, thereby enhancing the device's operational characteristics and distinguishing it from less specific configurations.

In a further implementation of the device according to the first aspect, the at least one lateral semiconductor element comprises a first load terminal and a second load terminal.

The implementation introduces a specific configuration for the lateral semiconductor element within the semiconductor device. It specifies that the lateral semiconductor element includes a first load terminal and a second load terminal, both of which are positioned on the front side of the semiconductor body. This arrangement establishes a mechanism of communication between the lateral semiconductor element and the external circuitry or system to which the device is connected. The first and second load terminals serve as the points of electrical contact through which a load current is conducted. The implementation further defines the functionality of the lateral semiconductor element, stating that it is designed to conduct a load current between the first load terminal and the second load terminal. This feature brings a clear operational purpose to the lateral semiconductor element, emphasizing its role in facilitating current flow within the device. By specifying that both terminals are located on the front side, the implementation highlights a structural and functional design choice that may simplify integration with other components or systems, as it avoids the need for electrical connections on the back side of the semiconductor body. This configuration may also contribute to improved thermal management or reduced manufacturing complexity, as the back side of the semiconductor body is already described in the aspect as being covered at least partly by an insulating layer and incorporating doped regions with specific characteristics. The implementation thus complements the aspect by detailing how the lateral semiconductor element interacts with the rest of the device and external systems, while also potentially offering advantages in terms of design efficiency and functionality.

In a further implementation of the device according to the first aspect, the at least one lateral semiconductor element comprises a first doped element region in ohmic connection to the first load terminal, one or more of the at least one second doped regions encompass a vertical projection of the first doped element region on the back side.

The implementation introduces a specific mechanism of communication between the lateral semiconductor element and the second doped regions by defining a spatial and electrical relationship. The lateral semiconductor element includes a first doped element region that is in ohmic connection to the first load terminal, ensuring a low-resistance electrical pathway for current flow. This establishes a direct functional link between the lateral semiconductor element and the external circuitry connected to the first load terminal. The new feature brought by this implementation is the spatial alignment of one or more of the second doped regions with the vertical projection of the first doped element region on the back side of the semiconductor body. This alignment implies that the second doped regions are strategically positioned to correspond to the location of the first doped element region when viewed along a vertical axis. This spatial relationship enhances the structural and functional integration of the device by potentially optimizing the distribution of electric fields, improving current flow, or facilitating heat dissipation. Furthermore, the implementation implicitly suggests that the second doped regions, which differ from the first doped region in doping concentration or conductivity type, may play a role in modulating the electrical characteristics of the device, such as breakdown voltage, leakage current, or switching performance. By encompassing the vertical projection of the first doped element region, the second doped regions may also contribute to the robustness of the device by providing additional pathways for current or by influencing the behavior of the lateral semiconductor element under specific operating conditions. The implementation thus refines the structural and functional interplay between the lateral semiconductor element and the second doped regions, building upon the foundational elements of the aspect to introduce a more precise and potentially advantageous configuration.

In a further implementation of the device according to the first aspect, the at least one lateral semiconductor element is a diode.

The implementation introduces a specific implementation of the at least one lateral semiconductor element within the semiconductor device, specifying that it can be a diode, a bipolar transistor, a field effect transistor, a junction transistor, or an insulated-gate bipolar transistor (IGBT). This implementation refines the broader scope of the aspect by identifying particular types of lateral semiconductor elements that may be incorporated into the device region of the semiconductor body. The mechanisms of communication between components in this context are inherently tied to the electrical and physical interactions facilitated by the specified lateral semiconductor elements. For instance, if the lateral semiconductor element is a diode, the communication mechanism involves unidirectional current flow, which may be used for rectification or signal demodulation. If the element is a bipolar transistor, the communication mechanism involves current amplification through the interaction of the emitter, base, and collector regions, enabling signal processing or switching functions. A field effect transistor, on the other hand, relies on the modulation of current flow through a channel by an electric field applied to the gate, which is critical for digital logic and analog signal amplification. A junction transistor would similarly involve current control through junction-based interactions, while an IGBT combines the high input impedance and fast switching characteristics of a field effect transistor with the high current-carrying capability of a bipolar transistor, making it suitable for power applications.

In a further implementation of the device according to the first aspect, further comprising one or more adhesion promotion layers below the insulating layer; and a carrier wafer arranged to the semiconductor body via the one or more adhesion promotion layer.

The implementation introduces additional structural and functional features to the semiconductor device by specifying the inclusion of one or more adhesion promotion layers positioned below the insulating layer, as well as a carrier wafer that is arranged to the semiconductor body through these adhesion promotion layers. The mechanisms of communication between the components are established through the physical and functional interaction of the adhesion promotion layer with both the insulating layer and the carrier wafer. The adhesion promotion layer serves as an intermediary that enhances the bonding strength and stability between the semiconductor body and the carrier wafer, ensuring a robust mechanical and thermal interface. This layer likely facilitates improved adhesion by modifying surface properties, such as surface energy or chemical compatibility, thereby addressing potential issues like delamination or mechanical stress that could arise during fabrication or operation. The carrier wafer, in turn, provides structural support to the semiconductor body, which is particularly critical in applications where the semiconductor body may be thinned or subjected to mechanical handling during processing. The introduction of these features brings several advantages to the semiconductor device. The adhesion promotion layer contributes to the reliability and durability of the device by mitigating risks associated with weak bonding interfaces, such as cracking or separation under thermal cycling or mechanical stress. This is especially relevant in high-performance or high-reliability applications where the device may be exposed to extreme conditions. The carrier wafer, by providing additional mechanical support, enables the use of thinner semiconductor bodies, which can be advantageous for reducing overall device thickness, improving thermal dissipation, or achieving specific electrical characteristics. Furthermore, the combination of the adhesion promotion layer and the carrier wafer may facilitate advanced manufacturing techniques, such as wafer-level packaging or three-dimensional integration, by providing a stable platform for further processing. These new features, therefore, enhance the structural integrity, manufacturing versatility, and operational reliability of the semiconductor device, while maintaining compatibility with the core elements and functionalities described in the aspect.

A second aspect of the invention provides method for manufacturing a semiconductor device comprising the following steps: providing a semiconductor body having a front side and a back side opposite to the front side, a device region within the semiconductor body at the front side, wherein the device region comprises at least one lateral semiconductor element; and a first doped region of a second conductivity type between the device region and the back side, wherein the first doped region overlaps first portions of the back side; forming at least one second doped region within the semiconductor body, wherein the at least one second doped region overlaps second portions of the back side, wherein the first doped region is arranged between the device region and the at least one second doped region; and forming an insulating layer at least partly covering the back side of the semiconductor body; wherein the at least one second doped region differs from the first doped region in at least one of the doping concentration by at least 20%, and/or the conductivity type of the doping; wherein both the first portions of the back side and the second portions of the back side laterally overlap with the insulating layer.

The subject matter describes a method for manufacturing a semiconductor device, involving specific steps and structural features. The terms used in the aspect are explained as follows:

A “semiconductor body” refers to the base material, typically silicon or another semiconductor material, used to construct the device. It has a “front side” and a “back side,” which are opposite surfaces of the body. The “front side” is where the active components of the device are typically formed, while the “back side” is the opposite surface.

A “device region” is a defined area within the semiconductor body, located at the front side, where at least one “lateral semiconductor element” is formed. A lateral semiconductor element may refer to a component such as a transistor or diode, where the current flow or operation occurs in a direction parallel to the surface of the semiconductor body.

A “first doped region” is a region within the semiconductor body that has been intentionally infused with impurities to achieve a specific “second conductivity type.” Conductivity type refers to whether the region is doped to be n-type (electron carriers) or p-type (hole carriers). This first doped region is positioned between the device region and the back side and overlaps “first portions” of the back side.

A “second doped region” is another doped area within the semiconductor body, which overlaps “second portions” of the back side. The second doped region is distinct from the first doped region in at least one characteristic, such as the “doping concentration” (the density of dopant atoms) differing by at least 20%, or the “conductivity type” being different (e.g., n-type versus p-type).

An “insulating layer” is a material layer, such as silicon dioxide, that electrically isolates parts of the semiconductor body. This layer is formed to at least partially cover the back side of the semiconductor body. Both the first portions and the second portions of the back side, which correspond to the first and second doped regions, respectively, laterally overlap with this insulating layer.

The described method provides advantages such as improved control over the electrical properties of the semiconductor device by introducing distinct doping profiles and conductivity types. The arrangement of the doped regions and the insulating layer enhances the device's performance, reliability, and isolation characteristics, which are critical for advanced semiconductor applications.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 illustrates a vertical projection of a semiconductor device from a top view;

FIG. 2 illustrates a schematic lateral section of the semiconductor device of FIG. 1;

FIG. 3 illustrates a vertical projection of a semiconductor device of another embodiment from a top view.

### DETAILED DESCRIPTION

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

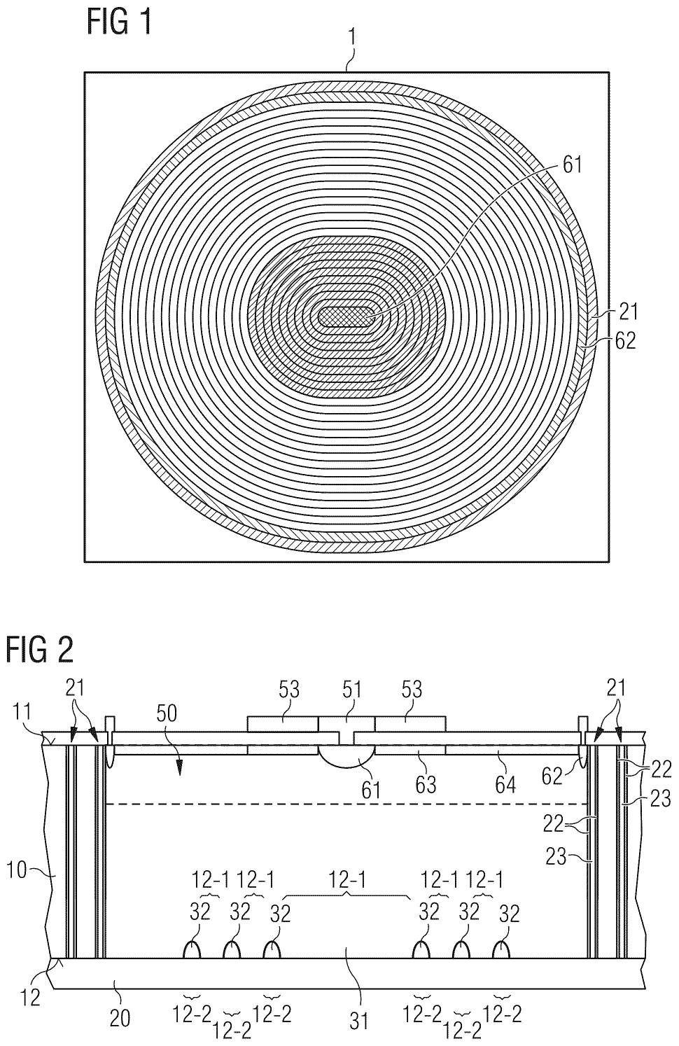

FIG. 1 illustrates a top view of a semiconductor device 1, which comprises a concentric arrangement of various regions and structures. The semiconductor device 1 comprises a device region 50, in an exemplary MOSFET configuration. The MOSFET comprises an emitter region 61 which is centrally located and surrounded by a collector region 62. The insulating trenches 21 are depicted as concentric rings encircling the emitter region 61 and the collector region 62, providing electrical isolation between these regions and other components of the semiconductor device 1. The arrangement of the insulating trenches 21 suggests a design that ensures effective isolation and structural integrity within the device region 50.

FIG. 2 provides a cross-sectional view of the semiconductor device 1, detailing the structural and material composition of the device. The semiconductor body 10 is shown as the primary substrate, with its front side 11 and back side 12. The back side 12 is divided into first portions 12-1 and second portions 12-2. The first doped region 31 overlaps the back side 12 in the first portions 12-1, while the second doped regions 32 overlap the back side 12 in the second portions 12-2. The insulating layer 20 is positioned on the back side 12 and may completely overlap both the first portions 12-1 and the second portions 12-2, thereby covering the first doped region 31 and the second doped regions 32.

The insulating trenches 21 extend from the front side 11 into the semiconductor body 10 and terminate at the insulating layer 20. Each insulating trench 21 comprises a trench oxide 22 lining the inner walls and a trench filler 23 occupying the central volume. The trench filler 23 may consist of doped or undoped polysilicon or an insulating material such as silicon oxide (CVD oxide). The insulating trenches 21 provide electrical isolation between adjacent regions within the semiconductor body 10.

The device region 50 is located near the front side 11 and includes the emitter region 61, the body region 63, the extension region 64, and the collector region 62. The emitter region 61 is positioned above the body region 63, which is in turn adjacent to the extension region 64. The collector region 62 is located laterally to the emitter region 61 and is separated by the insulating trenches 21. The trench oxide 22 and trench filler 23 within the insulating trenches 21 ensure electrical isolation between the emitter region 61 and the collector region 62.

The insulating layer 20, which may comprise a thermally grown oxide and/or a CVD oxide, is positioned beneath the semiconductor body 10 and provides additional electrical isolation. The insulating layer 20 may completely cover the first doped region 31 and the second doped regions 32, ensuring that the back side 12 is electrically insulated from the active regions of the semiconductor device 1.

The front side 11 of the semiconductor body 10 includes contact structures 51 and 53, which are connected to the emitter region 61 and the collector region 62, respectively. These contact structures facilitate electrical connections to external circuits or systems. The arrangement of the contact structures 51 and 53 ensures efficient electrical interfacing with the emitter region 61 and the collector region 62 while maintaining the structural integrity of the semiconductor device 1.

At the front side 11 of the semiconductor body 10 is also a gate structure present, the gate structure comprising an insulated gate electrode 53.

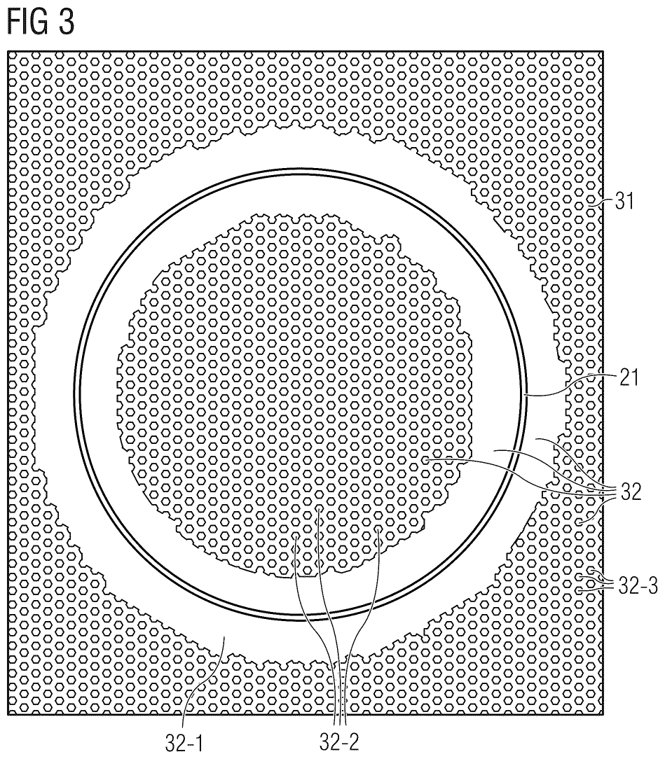

FIG. 3 illustrates a top-down view of a semiconductor device 1, specifically detailing the arrangement of various doped regions and insulating trenches within the semiconductor body 10. The figure prominently features an insulating trench 21, which forms a closed-loop structure. This insulating trench 21 is surrounded by and interacts with multiple doped regions, as described below.

The first doped region 31 is distributed across the semiconductor body 10 and is depicted as a uniform pattern of circular elements. This first doped region 31 extends across the majority of the back side area, providing a foundational layer for the device. Furthermore, second doped regions 32 are present. These second doped regions 32 are further subdivided into specific portions based on their spatial relationship to the insulating trench 21.

The inside of the loop formed by the insulating trench 21 comprises second doped regions 32-2. These regions are located entirely within the enclosed area defined by the insulating trench 21 and are distinct from the surrounding regions. Outside the loop formed by the insulating trench 21, second doped regions 32-3 are present. These regions are located external to the insulating trench 21 and are distributed in a manner similar to the second doped region 32-2. In the vicinity of the insulating trench 21, a second doped regions 32-1 is arranged in an adjacent manner, as indicated by reference 32-1 to the trench 21. This second doped region 32-1 creates a buffer zone immediately adjacent to the insulating trench 21.

The insulating trench 21 itself is depicted as a continuous, closed-loop structure, which may comprise an insulating layer 20, trench oxide 22, and trench filler 23 (not explicitly labeled in this figure but inferred from the context of the reference signs). This trench serves to electrically isolate the regions within its boundary from those outside, thereby defining distinct operational zones within the semiconductor device 1.

The spatial configuration ensures that the device operates as intended, with the insulating trench 21 providing necessary isolation and the doped regions enabling specific electrical properties. The second doped regions 21 in the vicinity of the insulating trench 21 (ref 32-1) further enhances the isolation characteristics, preventing unintended electrical interactions between the regions inside and outside the loop and lowering the field strength around the trench 21.

The figure provides a detailed schematic representation of the spatial relationships and functional integration of the insulating trench 21 and the doped regions within the semiconductor body 10, forming a critical aspect of the semiconductor device 1.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device, comprising:
a semiconductor body having a front side and a back side opposite to the front side;
a device region within the semiconductor body at the front side, wherein the device region comprises at least one lateral semiconductor element;
a first doped region of a second conductivity type between the device region and the back side, wherein the first doped region overlaps first portions of the back side;
at least one second doped region within the semiconductor body, wherein the at least one second doped region overlaps second portions of the back side, wherein the first doped region is arranged between the device region and the at least one second doped region; and
an insulating layer at least partly covering the back side of the semiconductor body,
wherein the at least one second doped region differs from the first doped region in at least one of a doping concentration by at least 20% and/or a conductivity type of the doping,
wherein both the first portions of the back side and the second portions of the back side laterally overlap with the insulating layer.

2. The semiconductor device of claim 1, wherein the at least one second doped region is of the second conductivity type.

3. The semiconductor device of claim 1, wherein the doping concentration of the at least one second doped region is at least one magnitude higher than the doping concentration of the first doped region.

4. The semiconductor device of claim 1, wherein the first doped region and/or the at least one second doped region adjoin the back side.

5. The semiconductor device of claim 1, wherein two different ones of the second portions of the back side are completely separated from each other by one or more of the first portions.

6. The semiconductor device of claim 1, wherein the first portions of the back side are completely covered by the insulating layer.

7. The semiconductor device of claim 1, wherein the second portions of the back side are completely covered by the insulating layer.

8. The semiconductor device of claim 1, wherein one or more of the at least one second doped region is shaped as a closed loop.

9. The semiconductor device of claim 1, wherein in a top view, a plurality of second doped regions is arranged according to a dot matrix.

10. The semiconductor device of claim 9, wherein in a top view:
a first subset of the second doped regions is arranged according to a first dot matrix inside a closed loop; and/or
a second subset of the second doped regions is arranged according to a second dot matrix outside the closed loop.

11. The semiconductor device of claim 1, further comprising:
an insulating trench extending from the front side to the back side of the semiconductor body, laterally confining the device region.

12. The semiconductor device of claim 11, wherein the insulating trench comprises a trench dielectric adjoining the insulating layer.

13. The semiconductor device of claim 11, wherein in a top view, the insulating trench is shaped as a closed loop.

14. The semiconductor device of claim 11, wherein the at least one second doped region laterally adjoins the whole inside of the insulating trench.

15. The semiconductor device of claim 1, wherein the at least one lateral semiconductor element comprises a first load terminal and a second load terminal, both the first load terminal and the second load terminal being arranged at the front side of the semiconductor body, and wherein the at least one lateral semiconductor element is configured to conduct a load current between the first load terminal and the second load terminal.

16. The semiconductor device of claim 15, wherein the at least one lateral semiconductor element comprises a first doped element region in ohmic connection to the first load terminal, and wherein one or more of the at least one second doped region encompasses a vertical projection of the first doped element region on the back side.

17. The semiconductor device of claim 15, wherein the at least one lateral semiconductor element is a diode, a bipolar transistor, a field effect transistor, a junction transistor, or an IGBT.

18. The semiconductor device of claim 1, further comprising:
one or more adhesion promotion layers below the insulating layer; and
a carrier wafer arranged to the semiconductor body via the one or more adhesion promotion layers.

19. A method for manufacturing a semiconductor device, the method comprising:
providing a semiconductor body having a front side and a back side opposite to the front side, a device region within the semiconductor body at the front side, wherein the device region comprises at least one lateral semiconductor element, and a first doped region of a second conductivity type between the device region and the back side, wherein the first doped region overlaps first portions of the back side;
forming at least one second doped region within the semiconductor body, wherein the at least one second doped region overlaps second portions of the back side, wherein the first doped region is arranged between the device region and the at least one second doped region; and
forming an insulating layer at least partly covering the back side of the semiconductor body,
wherein the at least one second doped region differs from the first doped region in at least one of a doping concentration by at least 20% and/or a conductivity type of the doping,
wherein both the first portions of the back side and the second portions of the back side laterally overlap with the insulating layer.
